(19) United States
(12) Patent Application Publication
(10) Pub. No.: US 2016/0103247 A1
(43) Pub. Date: Apr. 14, 2016

(54) NEAR INFRARED RADIATION-ABSORBING COMPOSITION, NEAR INFRARED RADIATION CUT-OFF FILTER AND PRODUCTION METHOD THEREFOR, AND CAMERA MODULE AND PRODUCTION METHOD THEREFOR

(71) Applicant: FUJIFILM Corporation, Tokyo (JP)

(72) Inventors: Seiichi HITOMI, Haibara-gun (JP); Takeshi INASAKI, Haibara-gun (JP)

(73) Assignee: FUJIFILM Corporation, Tokyo (JP)

(21) Appl. No.: 14/972,321

(22) Filed: Dec. 17, 2015

Related U.S. Application Data
(63) Continuation of application No. PCT/JP2014/067309, filed on Jun. 30, 2014.

(30) Foreign Application Priority Data
Jul. 1, 2013 (JP) 2013-137992

(51) Int. Cl. G02B 1/04; H01L 27/146; G02B 5/20; C08G 77/398; H04N 5/33; H04N 5/335

(52) U.S. Cl. CPC G02B 1/04; H04N 5/33; H04N 5/335; G02B 5/208; C08G 77/398; H01L 27/14685

(57) ABSTRACT

Provided are a near infrared radiation-absorbing composition capable of forming a cured film having excellent heat resistance while maintaining high near infrared radiation-shielding properties, a near infrared radiation cut-off filter and a production method therefor, and a camera module and a production method therefor. The near infrared radiation-absorbing composition includes a copper compound obtained from a reaction between a siloxane (A1) having an acid group or a salt thereof and a copper component.

### CROSS-REFERENCE TO RELATED APPLICATIONS

This application is a Continuation of PCT International Application No. PCT/JP2014/067309 filed on Jun. 30, 2014, which claims priority under 35 U.S.C §119(a) to Japanese Patent Application No. 2013-137992 filed on Jul. 1, 2013. Each of the above application(s) is hereby expressly incorporated by reference, in its entirety, into the present application.

### BACKGROUND OF THE INVENTION

1. Field of the Invention

The present invention relates to a near infrared radiation-absorbing composition, a near infrared radiation cut-off filter and a production method therefor, and a camera module and a production method therefor.

2. Description of the Related Art

In recent years, a CCD or CMOS which is a solid-state imaging element for color images has been used for video cameras, digital still cameras, mobile phones equipped with a camera function, and the like. In the solid-state imaging element, since a silicon photodiode having sensitivity to near infrared radiation is used in the light receiving section, it is necessary to correct the luminosity factor, and a near infrared radiation cut-off filter (hereinafter, also referred to as IR cut-off filter) is frequently used.

WO2009/140773A and Electrochemica Acta 37(9) 1615-1618 (1992) disclose that a polymer having a siloxane site in the main chain and an acid group or a salt thereof in a side chain is used for a proton-conducting film.

### SUMMARY OF THE INVENTION

Here, there is a demand for forming a cured film having excellent heat resistance while maintaining high near infrared radiation-shielding properties, particularly, a cured film which is transparent in the visible light range when heated (near infrared radiation cut-off filter).

The present invention intends to solve such problems, and an object of the present invention is to provide a cured film having excellent heat resistance while maintaining high near infrared radiation-shielding properties.

The present inventors found that the above-described problems can be solved by formulating a copper compound obtained from a reaction between a siloxane having an acid group or a salt thereof and a copper component into a near infrared radiation-absorbing composition.

Specifically, the above-described problems were solved using the following means <1>, preferably, means <2> to <11>.

<1> A near infrared radiation-absorbing composition including a copper compound obtained from a reaction between a siloxane (A1) having an acid group or a salt thereof and a copper component.

<2> The near infrared radiation-absorbing composition according to <1>, in which the acid group is at least one group selected from a group consisting of a phosphoric acid group, a carboxylic acid group, and a sulfonic acid group.

<3> The near infrared radiation-absorbing composition according to <1> or <2>, in which the siloxane (A1) includes at least one of a polymer having a repeating unit represented by Formula (A1-1), a cyclic siloxane, a siloxane having a ladder-like structure, a siloxane having a basket-like structure, and a siloxane having a random structure:

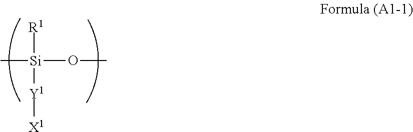

in Formula (A1-1), R¹ represents an alkyl group or an alkoxy group, Y¹ represents a divalent linking group, and X¹ represents an acid group or a salt thereof.

<4> The near infrared radiation-absorbing composition according to any one of <1> to <3>, in which the acid group is a sulfonic acid group.

<5> The near infrared radiation-absorbing composition according to <3>, in which the divalent linking group represents a linear, branched, or cyclic alkylene group, arylene group, —O—, —S—, —C(═O)—, —C(═O)O—, or a group made of a combination thereof.

<6> A near infrared radiation-absorbing composition including a copper complex in which an acid group ion site in a siloxane (A2) having an acid group ion is used as a ligand.

<7> A near infrared radiation cut-off filter obtained using the near infrared radiation-absorbing composition according to any one of <1> to <6>.

<8> The near infrared radiation cut-off filter according to <7>, in which, before and after heating at 200° C. or higher for five minutes, a percentage of change in absorbance at a wavelength of 400 nm and a percentage of change in absorbance at a wavelength of 800 nm are respectively 10% or lower.

<9> A production method for a near infrared radiation cut-off filter, including: a step of forming a near infrared radiation cut-off filter on a light-receiving side of a solid-state imaging element substrate by applying the near infrared radiation-absorbing composition according to any one of <1> to <6> thereto.

<10> A camera module including: a solid-state imaging element substrate; and a near infrared radiation cut-off filter disposed on a light-receiving side of the solid-state imaging element substrate, in which the near infrared radiation cut-off filter according to <7> or <8> is used.

<11> A production method for a camera module including a solid-state imaging element substrate and a near infrared radiation cut-off filter disposed on a light-receiving side of the solid-state imaging element substrate, including: a step of forming a near infrared radiation cut-off filter by applying the near infrared radiation-absorbing composition according to any one of <1> to <6> to a light-receiving side of the solid-state imaging element substrate.

According to the present invention, it has become possible to provide a cured film having excellent heat resistance while maintaining high near infrared radiation-shielding properties.

### BRIEF DESCRIPTION OF THE DRAWINGS

FIG. 1 is an imaginary view illustrating an example of a copper compound including a siloxane having an acid group ion and a copper ion in the present invention.

FIG. 2 is a schematic sectional view illustrating a constitution of a camera module including a solid-state imaging element according to an embodiment of the present invention.

FIG. 3 is a schematic sectional view of a solid-state imaging element substrate according to the embodiment of the present invention.

### DESCRIPTION OF THE PREFERRED EMBODIMENTS

Hereinafter, the contents of the present invention will be described in detail.

In the present specification, “to” used to express numerical ranges will be used with a meaning that numerical values before and after the “to” are included in the numerical ranges as the lower limit value and the upper limit value.

In the present specification, “(meth)acrylates” represent acrylates and methacrylates, “(meth)acrylic” represents acrylic and methacrylic, and “(meth)acryloyl” represents acryloyl and methacryloyl.

In the present specification, “monomers” and “monomers” refer to the same thing. In addition, “polymers” and “polymers” refer to the same thing.

In the present specification, regarding the denoting of a group (atomic group), a group not denoted with ‘substituted’ or ‘unsubstituted’ refers to both a group (atomic group) having no substituents and a group (atomic group) having a substituent.

A near infrared radiation-ray in the present invention refers to a ray having a maximum absorption wavelength in a range of 700 nm to 2500 nm and particularly in a range of 700 nm to 1000 nm.

<Near Infrared Radiation-Absorbing Composition>

A near infrared radiation-absorbing composition of the present invention (hereinafter, also referred to as the composition of the present invention) includes a copper compound obtained from a reaction between a siloxane (A1) having an acid group or a salt thereof and a copper component.

The copper compound obtained from a reaction between the siloxane (A1) and a copper component is, for example, a copper compound including a siloxane (A2) having an acid group ion and a copper ion and, more specifically, a copper complex in which an acid group ion site in the siloxane (A2) is used as a ligand. In the composition of the present invention, since the copper compound obtained from a reaction between the siloxane (A1) and a copper component has a siloxane bond (Si—O), it is possible to form a cured film having excellent heat resistance and humidity resistance.

<<Siloxane (A1) Having an Acid Group or a Salt Thereof>>

The siloxane (A1) is a compound having an acid group or a salt thereof and a siloxane bond and may be a high-molecular-weight siloxane (for example, a siloxane having a molecular weight of 1000 or higher) or a low-molecular-weight siloxane (for example, a siloxane having a molecular weight of lower than 1000). The number of the siloxanes (A1) used may be one or more.

The high-molecular-weight siloxane is preferably a polymer having a siloxane bond in the main chain and an acid group or a salt thereof in at least one of the main chain or a side chain and more preferably a polymer having the acid group or the salt thereof in a side chain.

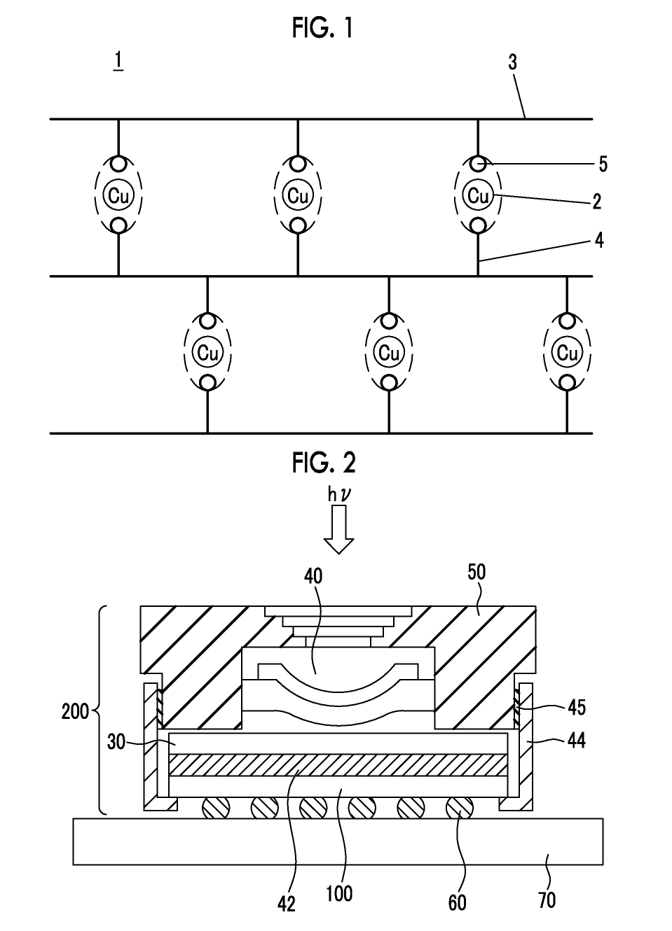

FIG. 1 is an imaginary view illustrating an example of the copper compound including the siloxane (A2) and a copper ion, in which 1 indicates the copper compound including the siloxane (A2) and a copper ion, 2 indicates the copper ion, 3 indicates the main chain of the polymer, 4 indicates a side chain of the polymer, and 5 indicates an acid group ion site 5 derived from the acid group or the salt thereof, respectively.

In a case in which a high-molecular-weight siloxane is used as the siloxane (A1), the acid group ion site is bonded to copper (for example, a coordination bond), and a crosslinked structure can be formed between side chains of the polymer from copper as an origination. In this case, even when the copper compound including the siloxane (A2) and a copper ion is heated, the structure thereof is not easily broken, and consequently, it is assumed that a cured film having superior heat resistance and humidity resistance can be obtained. In addition, in the present invention, since the acid group ion site in the siloxane (A2) and copper derived from the copper component can be bonded together, it is possible to further increase the content of copper in the composition of the present invention, and consequently, it is assumed that there is a tendency of near infrared radiation-shielding properties to further improve. In addition, there is an advantage that, even when the copper compound is heated, copper is not easily lost.

The acid group in the siloxane (A1) is not particularly limited as long as the acid group is capable of reacting with the above-described copper component, but is preferably an acid group capable of forming a coordination bond with the copper component. Specifically, the acid group is an acid group having an acid dissociation constant (pKa) of 12 or lower, and is preferably a phosphoric acid group, a carboxylic acid group, a sulfonic acid group, an imidic acid group, or the like, more preferably a phosphoric acid group, a carboxylic acid group, or a sulfonic acid group, and still more preferably a sulfonic acid group. Only one acid group or two or more acid groups may be used.

Examples of the salt of the acid group include metal salts of sodium salts and the like (particularly, alkali metal salts), tetrabutyl ammonium salts, and the like; and a metal salt is preferred, and an alkali metal salt is more preferred.

At least one acid group or salt thereof needs to be included in the siloxane (A1), and particularly, the acid group or the salt thereof is preferably bonded to a silicon atom constituting the siloxane (A1) directly or through a linking group.

In the siloxane (A1), the acid value derived from the acid group or the salt thereof is preferably 1 meq/g or higher and more preferably in a range of 2 meq/g to 7 meq/g.

The siloxane (A1) used in the present invention preferably includes a polymer having a repeating unit represented by Formula (A1-1) described below.

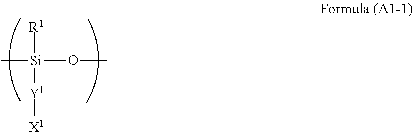

(In Formula (A1-1), R¹ represents an alkyl group or an alkoxy group, Y¹ represents a divalent linking group, and X¹ represents an acid group or a salt thereof.)

In Formula (A1-1), in a case in which R¹ represents an alkyl group, the number of carbon atoms in the alkyl group is preferably in a range of 1 to 10, more preferably in a range of 1 to 6, and still more preferably in a range of 1 to 3, and R¹ is particularly preferably a methyl group. In a case in which R¹ represents an alkoxy group, the number of carbon atoms in the alkoxy group is preferably in a range of 1 to 10, more preferably in a range of 1 to 6, and still more preferably in a range of 1 to 3, and R¹ is particularly preferably a methoxy group.

In Formula (A1-1), Y¹ is preferably an alkylene group, an arylene group, —O—, —S—, —C(═O)—, —C(═O)O—, or a group made of a combination thereof and more preferably an arylene group or a group made of a combination of a linear alkylene group and an arylene group.

The alkylene group may be any one of linear, branched, or cyclic alkylene groups and is preferably a linear alkylene group.

The number of carbon atoms in the linear alkylene group is preferably in a range of 1 to 20, more preferably in a range of 1 to 10, and still more preferably in a range of 1 to 5. In addition, the number of carbon atoms in the branched alkylene group is preferably in a range of 3 to 30, more preferably in a range of 3 to 15, and still more preferably in a range of 3 to 6. The cyclic alkylene group may be a monocyclic ring or a polycyclic ring. The number of carbon atoms in the cyclic alkylene group is preferably in a range of 3 to 20, more preferably in a range of 4 to 10, and still more preferably in a range of 6 to 10.

The number of carbon atoms in the arylene group is preferably in a range of 6 to 18 and more preferably in a range of 6 to 12, and the arylene group is particularly preferably a phenylene group.

In Formula (A1-1), X¹ is identical to the above-described acid group or salt thereof, and a preferred range thereof is also identical.

The siloxane (A1) may have only one type of repeating unit represented by Formula (A-1) or may have two or more types of repeating units.

Specific examples of the siloxane (A1) used in the present invention include the compounds shown in the following table and salts of the compounds, but are not limited thereto. In the following structures, Me represents a methyl group. In addition, in the following structures, n1 and n2 represent the molar ratios of individual repeating units, and n1:n2 is preferably in a range of 0.3:0.7 to 1.0:0. In the following compounds, for example, Si is bonded to an oxygen atom bonded to Si, thereby constituting a repeating unit.

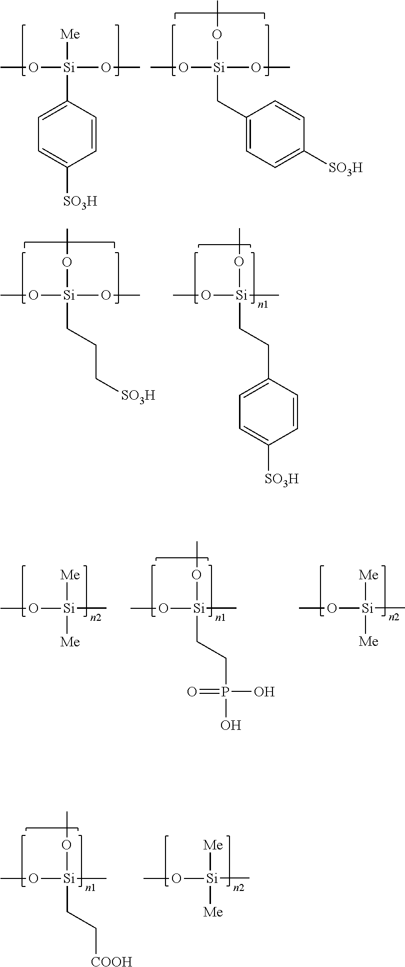

In a case in which the siloxane (A1) used in the present invention is a polymer having the repeating unit represented by Formula (A1-1), the weight-average molecular weight of the polymer is preferably 2000 or higher, more preferably in a range of 5000 to 200000, and still more preferably in a range of 10000 to 50000.

The weight-average molecular weight of the polymer is defined as polystyrene-equivalent values obtained from the measurement through GPC. For example, the weight-average molecular weight (Mw) of the polymer can be obtained using an HLC-8120 (manufactured by Tosoh Corporation), a TSK gel Multipore HXL-M (manufactured by Tosoh Corporation, 7.8 mm ID×30.0 cm) as a column, and tetrahydrofuran (THF) as an eluant.

In a case in which a high-molecular-weight siloxane is used as the siloxane (A1), the content of the copper compound obtained from a reaction between the siloxane (A1) and a copper component is preferably 2% by mass or higher and more preferably in a range of 5% by mass to 18% by mass of the total solid content of the composition of the present invention.

The low-molecular-weight siloxane is preferably a siloxane having two or more siloxane bonds in one molecule. Examples of the low-molecular-weight siloxane include siloxanes having a basket-like structure, siloxanes having a cyclic structure, siloxanes having a ladder-like structure, siloxanes having a random structure, and the like.

As an example of the basket-like structure, a structure represented by [RSiO_{3/2}]ₙ can be used. Examples thereof include silsesquioxane of General Formula (A2-1) below represented by [RSiO_{3/2}]₈, silsesquioxane of General Formula (A2-2) below represented by [RSiO_{3/2}]₁₀, silsesquioxane of General Formula (A3-3) below represented by [RSiO_{3/2}]₁₂, silsesquioxane of General Formula (A2-4) below represented by [RSiO_{3/2}]₁₄, and silsesquioxane of General Formula (A2-5) below represented by a chemical formula of [RSiO_{3/2}]₁₆.

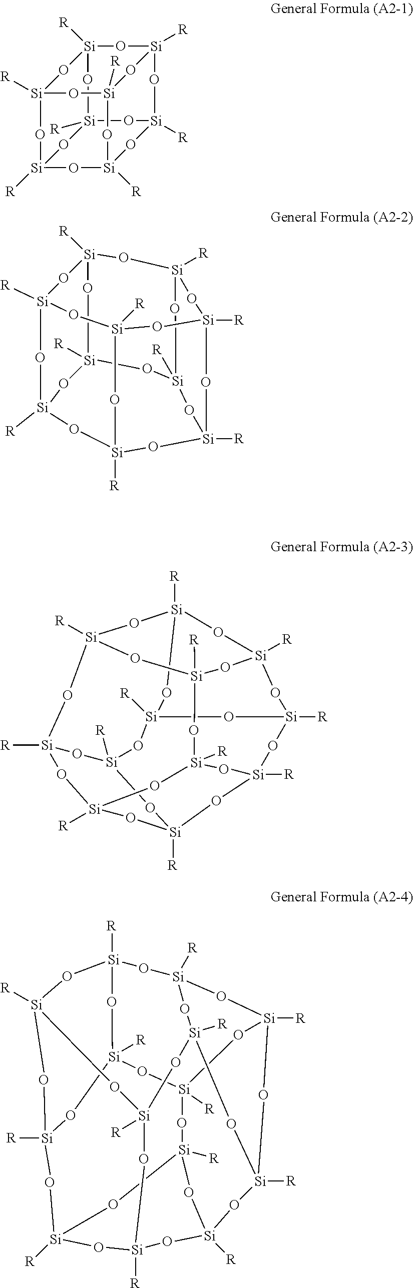

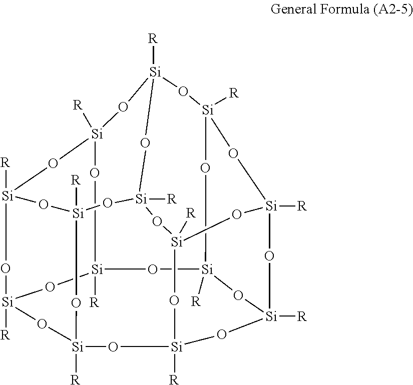

In addition, as the basket-like structure, a structure represented by [RSiO_{3/2}]ₙ₋ₘ(O_{1/2}/H)₂₊ₘ (n is an integer from 6 to 20 and m is 0 or 1) in which some silicon-oxygen bonds are partially cleaved can be used. Examples thereof include a partially-cleaved trisilanol body of General Formula (A2-1), silsesquioxane of General Formula (A2-6) below represented by [RSiO_{3/2}]₇(O_{1/2}H)₃, silsesquioxane of General Formula (A2-7) below represented by [RSiO_{3/2}]₈(O_{1/2}H)₂, and silsesquioxane of General Formula (A2-8) below represented by [RSiO_{3/2}]₈(O_{1/2}H)₂.

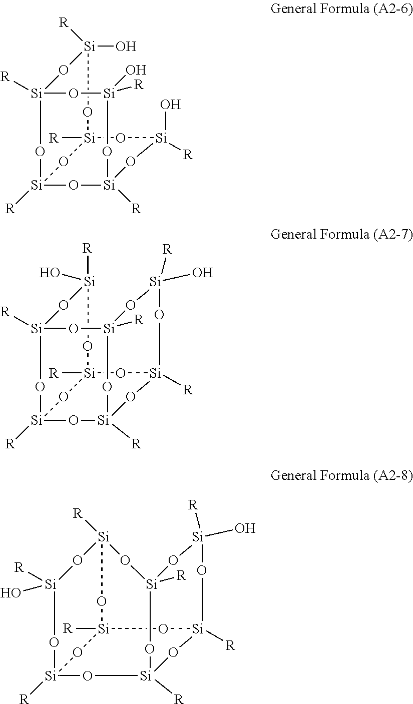

In the low-molecular-weight siloxane having the acid group or the salt thereof, at least one of R's in the above-described general formula is substituted with an acid group or a salt thereof. The acid group or the salt thereof is identical to the acid group or the salt thereof in the above-described high-molecular-weight siloxane, and a preferred range thereof is also identical.

In addition, examples of R in General Formulae (A2-1) to (A2-8) include a hydrogen atom, a (meth)acryl group, a saturated hydrocarbon group having 1 to 20 carbon atoms, an alkenyl group having 2 to 20 carbon atoms, an aralkyl group having 7 to 20 carbon atoms, and an aryl group having 6 to 20 carbon atoms. Among these, R is preferably a polymerizable functional group capable of a polymerization reaction.

Examples of the saturated hydrocarbon group having 1 to 20 carbon atoms include a methyl group, an ethyl group, an n-propyl group, an i-propyl group, a butyl group (an n-butyl group, an i-butyl group, a t-butyl group, a sec-butyl group, or the like), a pentyl group (an n-pentyl group, an i-pentyl group, a neopentyl group, a cyclopentyl group, or the like), a hexyl group (an n-hexyl group, an i-hexyl group, a cyclohexyl group, or the like), a heptyl group (an n-heptyl group, an i-heptyl group, or the like), an octyl group (an n-octyl group, an i-octyl group, a t-octyl group, or the like), a nonyl group (an n-nonyl group, an i-nonyl group, or the like), a decyl group (a n-decyl group, an i-decyl group, or the like), an undecyl group (an n-undecyl group, an i-undecyl group, or the like), a dodecyl group (an n-dodecyl group, an i-dodecyl group, or the like), and the like.

Examples of the alkenyl group having 2 to 20 carbon atoms include non-cyclic alkenyl groups and cyclic alkenyl groups. Examples thereof include a vinyl group, a propenyl group, a butenyl group, a pentenyl group, a hexenyl group, a cyclohexenyl group, a cyclohexenylethyl group, a norbornenylethyl group, a heptenyl group, an octenyl group, a nonenyl group, a decenyl group, an undecenyl group, a dodecenyl group, and the like.

Examples of the aralkyl group having 7 to 20 carbon atoms include a benzyl group, a phenethyl group, and a benzyl group or a phenethyl group in which one or more of alkyl groups having 1 to 13 carbon atoms, preferably having 1 to 8 carbon atoms, are substituted, and the like.

Examples of the aryl group having 6 to 20 carbon atoms include a phenyl group and a tolyl group or a phenyl group, a tolyl group, and a xylyl group which are substituted with an alkyl group having 1 to 14 carbon atoms and preferably 1 to 8 carbon atoms.

In a case in which the low-molecular-weight siloxane is used as the siloxane (A1), the content of the copper compound obtained from a reaction between the siloxane (A1) and a copper component is preferably 2% by mass or higher and more preferably in a range of 5% by mass to 18% by mass of the total solid content of the composition of the present invention.

The siloxane (A1) used in the present invention is obtained by, for example, reacting the above-described acid group with a siloxane.

The high-molecular-weight siloxane having the acid group or the salt thereof can be obtained according to, for example, the method illustrated in FIG. 1 of Electrochemica Acta 37(9) (1992) or the method illustrated in FIG. 2 of WO2009/140773A.

In addition, the low-molecular-weight siloxane having the acid group or the salt thereof can be obtained by, for example, reacting the above-described acid group with a commercially available compound of Sigma-Aldrich Co., LLC., Hybrid Plastic, Chisso Corporation, Azmax.co, or the like or a SQ series put on the market by Toagosei Co., Ltd.

<<Copper Component>>

The copper component is preferably a compound including divalent copper. The content of copper in the copper component used in the present invention is preferably in a range of 2% by mass to 40% by mass and more preferably in a range of 5% by mass to 40% by mass. Only one copper component may be used or two or more copper components may be used. As the copper component, it is possible to use, for example, a copper oxide or a copper salt. The copper salt is more preferably divalent copper. Examples of the copper salt include copper hydroxide, copper acetate, copper chloride, copper formate, copper stearate, copper benzoate, copper ethylacetoacetate, copper pyrophosphate, copper naphthenate, copper citrate, copper nitrate, copper sulfate, copper carbonate, copper chlorate, copper (meth)acrylate, and copper perchlorate, and copper hydroxide, copper acetate, copper chloride, copper sulfate, copper benzoate, and copper (meth)acrylate are preferred, and copper hydroxide, copper acetate, and copper sulfate are particularly preferred.

The amount of the copper component reacted with the siloxane (A1) is preferably in a range of 0.05 equivalent weights to 1 equivalent weight, more preferably in a range of 0.1 equivalent weights to 0.8 equivalent weights, and still more preferably in a range of 0.2 equivalent weights to 0.5 equivalent weights with respect to 1 equivalent weight of the acid group in the siloxane (A1) or the salt thereof. When the amount of the copper component is set in the above-described range, there is a tendency that a cured film having higher near infrared radiation-shielding properties is obtained.

The near infrared radiation-absorbing composition of the present invention needs to include the copper compound obtained from a reaction between the siloxane (A1) and the copper component and, if necessary, may include a near infrared radiation-absorbing compound, a solvent, a curable compound, a polymerization initiator, a binder polymer, a surfactant, and the like in addition to the copper component.

<Other Near Infrared Radiation-Absorbing Compounds>

For the purpose of further improving the near infrared radiation-absorbing function of the composition of the present invention, a near infrared radiation-absorbing compound other than the copper compound obtained from the reaction between the siloxane (A1) and the copper component may be formulated into the composition of the present invention. The near infrared radiation-absorbing compound other than the copper compound, which is used in the present invention, is not particularly limited as long as the near infrared radiation-absorbing compound has a maximum absorption wavelength generally in a range of 700 nm to 2500 nm and preferably in a range of 700 nm to 1000 nm (near infrared radiation range). Only one near infrared radiation-absorbing compound or two or more near infrared radiation-absorbing compounds may be formulated.

Examples of the near infrared radiation-absorbing compound include a pyrrolo pyrrole pigment, a copper compound, a cyanine-based pigment, a phthalocyanine-based compound, an immonium-based compound, a thiol complex-based compound, a transition metal oxide-based compound, a squarylium-based pigment, a naphthalocyanine-based pigment, a quotarrylene-based pigment, a dithiol metal complex-based pigment, a croconium compound, and the like, and a copper compound is preferred, and a copper complex is more preferred.

In a case in which the near infrared radiation-absorbing compound is formulated into the composition, the ratio (mass ratio) between the copper compound obtained from the reaction between the siloxane (A1) and the copper component and the near infrared radiation-absorbing compound is preferably set in a range of 50:50 to 95:5 and more preferably set in a range of 70:30 to 90:10.

In a case in which the near infrared radiation-absorbing compound is a copper complex, examples of a ligand L coordinating copper include sulfonic acid, carboxylic acid, and compounds having carbonyl (ester, ketone), an amine, an amide, a sulfonamide, urethane, urea, an alcohol, or a thiol. Among these, carboxylic acid and sulfonic acid are preferred, and sulfonic acid is more preferred.

Examples of the copper complex include a copper complex represented by the following formula.

Cu(L)ₙ₁.(X)ₙ₂

In the above-described formula, L represents a ligand coordinating copper, X is not present or represents a halogen atom, H₂O, NO₃, ClO₄, SO₄, CN, SCN, BF₄, PF₆, BPh₄ (Ph represents a phenyl group), or an alcohol. Each of n1 and n2 independently represents an integer from 1 to 4.

The ligand L has a substituent including C, N, O, and S as an atom capable of coordinating copper and more preferably has a group having a lone electron pair such as N, O, or S. The number of kinds of the group capable of coordinating copper in the molecule is not limited to one and may be two or more, and the group may or may not be dissociated. A preferred ligand L is identical to the above-described ligand L. In a case in which the group is not dissociated, X is not present.

The copper complex is a copper compound in which a copper central metal is coordinated with a ligand, and copper is generally divalent copper. The copper complex can be obtained by, for example, mixing and reacting a compound or a salt thereof which serves as the ligand with the copper component.

Preferred examples of the compound or the salt thereof which serves as the ligand include organic acid compounds (for example, a sulfonic acid compound and a carboxylic acid compound) and a salt thereof.

Particularly, the compound or the salt thereof are preferably a sulfonic acid compound represented by Formula (I) below and a salt thereof.

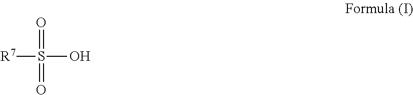

(In Formula (I), R⁷ represents a monovalent organic group.)

Specific examples of the monovalent organic group include linear, branched, or cyclic alkyl group, alkenyl group, and aryl group. Here, these groups may be groups linked through a divalent linking group (for example, an alkylene group, a cycloalkylene group, an arylene group, —O—, —S—, —CO—, —COO—, —OCO—, —SO₂—, —NR— (R is a hydrogen atom or an alkyl group), or the like). In addition, the monovalent organic group may have a substituent.

The number of carbon atoms in the linear or branched alkyl group is preferably in a range of 1 to 20, more preferably in a range of 1 to 12, and still more preferably in a range of 1 to 8.

The cyclic alkyl group may be either a monocyclic ring or a polycyclic ring. The number of carbon atoms in the cyclic alkyl group is preferably in a range of 3 to 20, more preferably in a range of 4 to 10, and still more preferably in a range of 6 to 10. The number of carbon atoms in the alkenyl group is preferably in a range of 2 to 10, more preferably in a range of 2 to 8, and still more preferably in a range of 2 to 4.

The number of carbon atoms in the aryl group is preferably in a range of 6 to 18, more preferably in a range of 6 to 14, and still more preferably in a range of 6 to 10.

Examples of the alkylene group, the cycloalkylene group, and the arylene group which are divalent linking groups include divalent linking groups derived by removing one hydrogen atom from the alkyl group, the cycloalkyl group, or the aryl group.

Examples of the substituent that the monovalent organic group may have include an alkyl group, a polymerizable group (for example, a vinyl group, a (meth)acryloyl group, an epoxy group, or an oxetane group), a halogen atom, a carboxyl group, a carboxylic acid ester group (for example, —CO₂CH₃) hydroxyl group, an amide group, and a halogenated alkyl group (for example, a fluoroalkyl group or a chloroalkyl group).

The molecular weight of the sulfonic acid compound represented by Formula (I) or the salt thereof is preferably in a range of 80 to 750, more preferably in a range of 80 to 600, and still more preferably in a range of 80 to 450.

Specific examples of the sulfonic acid compound represented by Formula (I) will be illustrated below, but are not limited thereto.

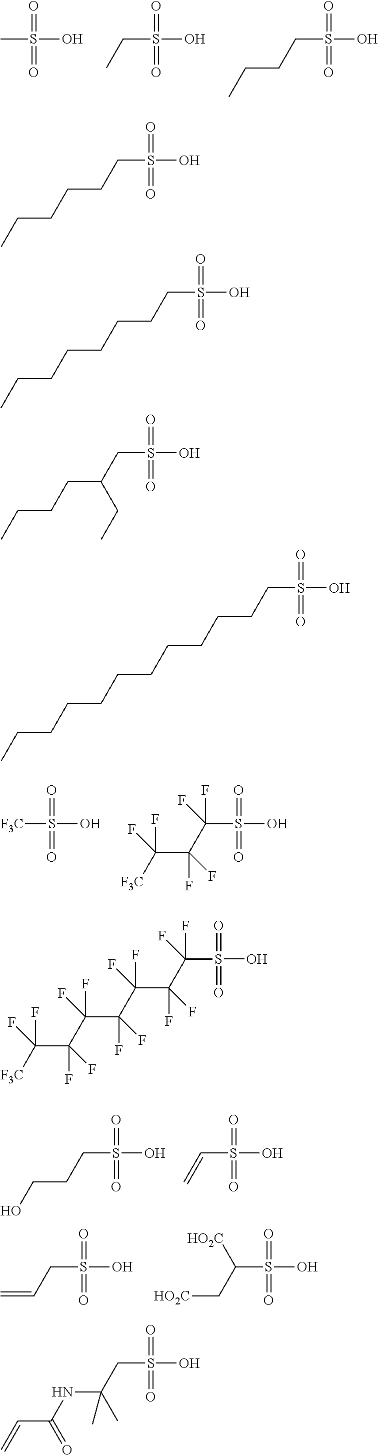

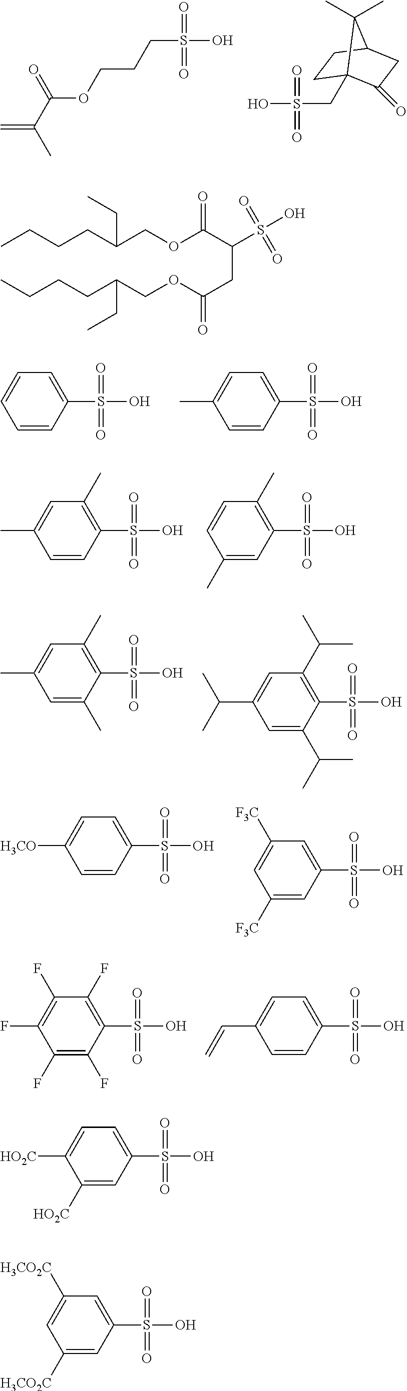

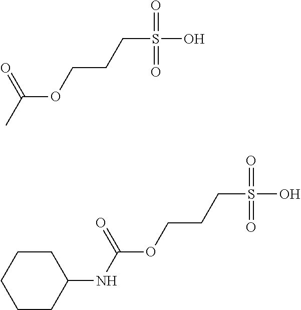 [SMILES: CC(=O)OCCCS(=O)(=O)O ; O=C(NC1CCCCC1)OCCCS(=O)(=O)O]

As the sulfonic acid compound that can be used in the present invention, a commercially available sulfonic acid can be used, and it is also possible to synthesize a sulfonic acid compound with reference to a well-known method.

Examples of the copper complex that can be used in the present invention include, in addition to the above-described copper complexes, copper complexes in which carboxylic acid is used as a ligand. As the carboxylic acid used in the copper complexes in which carboxylic acid is used as a ligand, for example, a compound represented by Formula (II) below can be used.

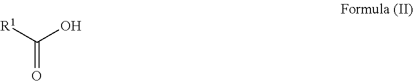

(In Formula (II), R¹ represents a monovalent organic group.)

In Formula (II), R¹ represents a monovalent organic group. The monovalent organic group is identical to, for example, the monovalent organic group in Formula (I) described above.

<Solvent>

Regarding a solvent used in the present invention, there is no particular limitation, any solvent can be appropriately selected depending on the purpose as long as the solvent is capable of uniformly dissolving or dispersing the respective components of the composition of the present invention, and preferred examples thereof include an aqueous solvent such as water or alcohols. In addition, additional preferred examples of the solvent used in the present invention include organic solvents, ketones, ethers, esters, aromatic hydrocarbons, halogenated hydrocarbons, dimethylformamide, dimethylacetamide, dimethylsulfoxide, sulfolane, and the like. Only one solvent may be used, or two or more solvents may be jointly used.

Specific examples of the alcohols, the aromatic hydrocarbons, and the halogenated hydrocarbons include those described in Paragraph “0136” and the like in JP2012-194534A and the content thereof is incorporated into the specification of the present application. In addition, specific examples of the esters, the ketones, and the ethers include those described in Paragraph “0497” in JP2012-208494A (Paragraph “0609” in the corresponding US2012/0235099A) and further include n-amyl acetate, ethyl propionate, dimethyl phthalate, ethyl benzoate, methyl sulfate, acetone, methyl isobutyl ketone, diethyl ether, ethylene glycol monobutyl ether acetate, propylene glycol monomethyl ether, propylene glycol monomethyl ether acetate, and the like.

The composition of the present invention particularly preferably includes water. The content of water is preferably in a range of 40% by mass to 95% by mass and more preferably in a range of 50% by mass to 85% by mass of the composition of the present invention.

In a case in which the composition of the present invention includes a solvent other than water, the percentage of the solvent is preferably in a range of 1% by mass to 50% by mass and more preferably in a range of 5% by mass to 30% by mass of the composition of the present invention. Only one solvent other than water may be used, or two or more solvents may be used.

<Curable Compound>

The composition of the present invention may further include a curable compound. The curable compound may be a polymerizing compound or a non-polymerizing compound such as a binder. In addition, the curable compound may be a thermosetting compound or a photocrosslinkable compound and is preferably a thermosetting composition due to its high reaction rate.

<<Compound Having Polymerizable Group>>

The composition of the present invention may include a compound having a polymerizable group (hereinafter, in some cases, referred to as “polymerizing compound”). A group of such compounds is widely known in the corresponding industrial field and, in the present invention, these compounds can be used without any particular limitation. The compounds may have any chemical form of, for example, a monomer, an oligomer, a prepolymer, a polymer, and the like.

<<Polymerizing Monomer and Polymerizing Oligomer>>

The composition of the present invention may include a monomer having a polymerizable group (polymerizing monomer) or an oligomer having a polymerizable group (polymerizing oligomer) (hereinafter, in some cases, the polymerizing monomer and the polymerizing oligomer will be collectively referred to as “the polymerizing monomer and the like”) as the polymerizing compound.

Examples of the polymerizing monomer and the like include unsaturated carboxylic acids (for example, acrylic acid, methacrylic acid, itaconic acid, crotonic acid, isocrotonic acid, maleic acid, and the like), esters thereof, and amides thereof and esters of an unsaturated carboxylic acid and an aliphatic polyhydric alcohol compound and amides of an unsaturated carboxylic acid and an aliphatic polyvalent amine compound are preferred. In addition, addition reactants of an unsaturated carboxylic acid ester or amide having a nucleophilic substituent such as a hydroxyl group, an amino group, or a mercapto group and a monofunctional or polyfunctional isocyanate or epoxy, dehydration and condensation reactants of a monofunctional or polyfunctional carboxylic acid, and the like are also preferably used. In addition, addition reactants of an unsaturated carboxylic acid ester or an amide having an electrophilic substituent such as an isocyanate group or an epoxy group and a monofunctional or polyfunctional alcohol, amine, or thiol and, furthermore, substitution reactants of an unsaturated carboxylic acid ester or amide having a leaving substituent such as a halogen group or a tosyloxy group and a monofunctional or polyfunctional alcohol, amine, or thiol are also preferred. As additional examples, it is also possible to use a group of compounds substituted with an unsaturated phosphonic acid, a vinyl benzene derivative such as styrene, a vinyl ether, an allyl ether, or the like instead of the above-described unsaturated carboxylic acid.

As the specific compounds thereof, the compounds described in Paragraphs “0095” to “0108” in JP2009-288705A can be preferably used even in the present invention.

In addition, as the polymerizing monomer and the like, it is possible to use a compound having an ethylenic unsaturated group which has at least one addition-polymerizing ethylene group and a boiling point of 100° C. or higher at normal pressure, and it is also possible to use a monofunctional (meth)acrylate, a difunctional (meth)acrylate, and a tri- or higher-functional (meth)acrylate (for example, tri- to hexafunctional (meth)acrylate).

Examples thereof include monofunctional acrylates or methacrylates such as polyethylene glycol mono(meth)acrylate, polypropylene glycol mono(meth)acrylate, and phenoxyethyl (meth)acrylate; and

substances obtained by adding ethylene oxide or propylene oxide to a polyfunctional alcohol such as polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl) ether, tri(acryloyloxyethyl) isocyanurate, glycerin, or trimethylolethane and then (meth)acrylating the mixture.

The polymerizing compound is ethyleneoxy-denatured pentaerythritol tetraacrylate (NK ester ATM-35E as a commercially available product: manufactured by Shin-Nakamura Chemical Co., Ltd.), dipentaerythritol triacrylate (KAYARAD D-330 as a commercially available product; manufactured by Nippon Kayaku Co., Ltd.), dipentaerythritol tetraacrylate (KAYARAD D-320 as a commercially available product; manufactured by Nippon Kayaku Co., Ltd.), dipentaerythritol penta(meth)acrylate (KAYARAD D-310 as a commercially available product; manufactured by Nippon Kayaku Co., Ltd.), dipentaerythritol hexa(meth)acrylate (KAYARAD DPHA as a commercially available product; manufactured by Nippon Kayaku Co., Ltd.), and structures in which the above-described (meth)acryloyl groups are bonded to each other through ethylene glycol and propylene glycol residues. In addition, the oligomer types thereof can also be used. It is also possible to use the compounds described in Paragraphs “0248” to “0251” in JP2007-269779A in the present invention.

Examples of the polymerizing monomer and the like include the polymerizing monomer and the like described in Paragraph “0477” in JP2012-208494A (Paragraph “0585” in the corresponding US2012/0235099A) and the content thereof is incorporated into the specification of the present application. In addition, DIGLYCERIN EO (ethylene oxide)-denatured (meth)acrylate (M-460 as a commercially available product; manufactured by Toagosei Co., Ltd.) can be used. Pentaerythritol tetraacrylate (manufactured by Shin-Nakamura Chemical Co., Ltd., A-TMMT) and 1,6-hexanediol diacrylate (manufactured by Nippon Kayaku Co., Ltd., KAYARAD HDDA) can also be used. The oligomer types thereof can also be used. Examples thereof include RP-1040 (manufactured by Nippon Kayaku Co., Ltd.).

In the present invention, as the monomer having an acid group, it is possible to use an ester of an aliphatic polyhydroxy compound and an unsaturated carboxylic acid which is a polyfunctional monomer provided with an acid group by reacting an unreacted hydroxyl group in an aliphatic polyhydroxy compound and a non-aromatic carboxylic anhydride. Examples of commercially available products thereof include ARONIX series M-305, M-510, M-520, and the like which are polybasic acid-denatured acryl oligomers manufactured by Toagosei Co., Ltd.

The acid value of the polyfunctional monomer having an acid group is in a range of 0.1 mgKOH/g to 40 mgKOH/g and preferably in a range of 5 mgKOH/g to 30 m-KOH/g. In a case in which two or more polyfunctional monomers having different acid groups are jointly used or polyfunctional monomers having no acid groups are jointly used, it is essentially required to adjust the polyfunctional monomers so that all the acid values of the polyfunctional monomers fall within the above-described range.

<<Polymer Having Polymerizable Group in Side Chain>>

The second aspect of the composition of the present invention may be an aspect in which a polymer having a polymerizable group in a side chain is provided as the polymerizing compound. Examples of the polymerizable group include an ethylenic unsaturated double-bonded group, an epoxy group, and an oxetanyl group.

<<Compound Having Epoxy Group or Oxetanyl Group>>

A third aspect of the present invention may be an aspect in which a compound having an epoxy group or an oxetanyl group is included as the polymerizing compound. Examples of the compound having an epoxy group or an oxetanyl group include polymers having an epoxy group in the side chain and polymerizing monomers or oligomers having two or more epoxy groups in the molecule and specific examples thereof include bisphenol A-type epoxy resins, bisphenol F-type epoxy resins, phenol novolac-type epoxy resins, cresol novolac-type epoxy resins, and aliphatic epoxy resins. In addition, examples thereof also include a monofunctional or polyfunctional glycidyl ether compound.

As the above-described compound, a commercially available product may be used or the compound can be obtained by introducing an epoxy group into the side chain in the polymer.

Regarding the commercially available product, for example, the description of Paragraphs “0191” and the like in JP2012-155288A can be referred to and the content thereof is incorporated into the specification of the present application.

Examples of the commercially available product include polyfunctional aliphatic glycidyl ether compounds such as DENACOL EX-212L, EX-214L, EX-216L, EX-321L, and EX-850L (all manufactured by Nagase ChemteX Corporation.). The above-described products are low-chlorine products and EX-212, X-214, EX-216, EX-321, EX-850, and the like, which are not low-chlorine products, can also be used in a similar manner.

Additionally, examples thereof include ADEKA RESIN EP-4000S, ADEKA RESIN EP-4003S, ADEKA RESIN EP-4010S, ADEKA RESIN EP-4011S (all manufactured by Adeka Corporation), NC-2000, NC-3000, NC-7300, XD-1000, EPPN-501, EPPN-502 (all manufactured by Adeka Corporation), JER1031S, and the like.

Furthermore, examples of the commercially available product of the phenol novolac-type epoxy resins include JER-157S65, JER-152, JER-154, JER-157S70 (all manufactured by Mitsubishi Chemical Corporation), and the like.

Specific examples of the polymer having an oxetanyl group in the side chain and the above-described polymerizing monomer or oligomer having two or more oxetanyl groups in the molecule that can be used include ARON OXETANE OXT-121, OXT-221, OX-SQ, and PNOX (all manufactured by Toagosei Co., Ltd.).

In a case in which the compound is synthesized by introducing an epoxy group into the side chain of the polymer, an epoxy group can be introduced by causing an introduction reaction in an organic solvent using, for example, a tertiary amine such as triethylamine or benzylmethylamine, a quaternary ammonium salt such as dodecyltrimethylammonium chloride, tetramethylammonium chloride, or tetraethylammonium chloride, pyridine, triphenylphosphine, or the like as a catalyst at a reaction temperature in a range of 50° C. to 150° C. for several hours to several tens of hours. The amount of an alicyclic epoxy unsaturated compound introduced can be controlled so that the acid value of the obtained polymer falls into a range of 5 KOH·mg/g to 200 KO·mg/g. In addition, the molecular weight can be set in a range of 500 to 5000000 and furthermore set in a range of 1000 to 500000 in terms of weight average.

As the epoxy unsaturated compound, a compound having a glycidyl group as the epoxy group such as glycidyl (meth)acrylate or allylglycidyl ether can be used. Regarding the above-described compound, for example, the description of Paragraph “0045” of JP2009-265518A can be referred to, and the content thereof is incorporated into the specification of the present application.

The details of how to use the polymerizing compound such as the structure of the polymerizing compound, whether to use the polymerizing compounds singly or jointly, and the amount of the polymerizing compound added can be arbitrarily set in accordance with the ultimate performance design of the near infrared radiation-absorbing composition. For example, from the viewpoint of sensitivity, a structure with a large content of an unsaturated group per molecule is preferred, and, in many cases, a di- or higher-functional polymerizing compound is preferred. In addition, from the viewpoint of increasing the strength of the near infrared radiation cut-off filter, a tri- or higher-functional polymerizing compound is preferred, and, furthermore, a method for adjusting both sensitivity and strength to be desired values by jointly using polymerizing compounds with different numbers of functional groups and different polymerizable groups (for example, acrylic acid esters, methacrylic acid esters, styrene-based compounds, or vinyl ether-based compounds) is also effective. In addition, regarding the compatibility with other components included in the near infrared radiation-absorbing composition (for example, a metallic oxide, a pigment, and a polymerization initiator) and the dispersibility thereof, a method of selecting and using the polymerizing compound is an important factor, and there are cases in which the compatibility can be improved by, for example, using a low-purity compound or jointly using two or more low-purity compounds. In addition, from the viewpoint of improving the adhesiveness to a hard surface of a support body or the like, it is also possible to select a specific structure.

The amount of the polymerizing compound added to the composition of the present invention can be set in a range of 1% by mass to 50% by mass and more preferably in a range of 1% by mass to 30% by mass of the total solid content excluding the solvent.

The number of the polymerizing compounds may be one or more and, in a case in which two or more polymerizing compounds are used, the total amount thereof needs to fall into the above-described range.

<Polymerization Initiator>

The composition of the present invention may include a polymerization initiator. The number of the polymerization initiators may be one or more and, in a case in which two or more polymerization initiators are used, the total amount thereof needs to fall into the following range. For example, the content of the polymerization initiator is preferably in a range of 0.01% by mass to 30% by mass, more preferably in a range of 0.1% by mass to 20% by mass, and still more preferably in a range of 0.1% by mass to 15% by mass of the solid content of the composition of the present invention.

The polymerization initiator is not particularly limited as long as the polymerization initiator has the capability of initiating the polymerization of the polymerizing compounds using either or both light and heat and can be appropriately selected depending on the purpose, but is preferably a photopolymerizing compound. In a case in which polymerization is initiated using light, the polymerization initiator preferably has sensitivity to light rays in an ultraviolet to visible light range.

In addition, in a case in which polymerization is initiated using heat, a polymerization initiator that is decomposed at a temperature in a range of 150° C. to 250° C. is preferred.

The polymerization initiator that can be used in the present invention is preferably a compound having at least an aromatic group, and examples thereof include acylphosphine compounds, acetophenone-based compounds, α-aminoketone compounds, benzophenone-based compounds, thioxanthone compounds, oxime compounds, hexaaryl biimidazole compounds, trihalomethyl compounds, azo compounds, organic peroxides, diazonium compounds, iodonium compounds, sulfonium compounds, azinium compounds, benzoin ether-based compounds, ketal derivative compounds, onium salt compounds such as metallocene compounds, organic boron salt compounds, disulfone compounds, and the like.

From the viewpoint of sensitivity, oxime compounds, acetophenone-based compounds, α-aminoketone compounds, trihalomethyl compounds, hexaaryl biimidazole compounds, and thiol compounds are preferred.

Regarding the acetophenone-based compounds, the trihalomethyl compounds, the hexaaryl biimidazole compounds, and the oxime compounds, specifically, the description in Paragraphs “0506” to “0510” in JP2012-208494A (“0622” to “0628” in the specification of the corresponding US2012/0235099A) and the like can be referred to, and the content thereof is incorporated into the specification of the present application.

The photopolymerization initiator is more preferably a compound selected from a group consisting of an oxime compound, acetophenone-based compounds, and an acylphosphine compound. More specifically, it is also possible to use, for example, the aminoacetophenone-based initiators described in JP1998-291969A (JP-H10-291969A), the acylphosphine oxide-based initiators described in JP4225898B, and the above-described oxime-based initiators, and, furthermore, as the oxime-based initiators, the compounds described in JP2001-233842A.

As the oxime compound, it is possible to use a commercially available product IRGACURE-OXE01 (manufactured by BASF) or IRGACURE-OXE02 (manufactured by BASF). As the acetophenone-based initiator, it is possible to use commercially available products IRGACURE-907, IRGACURE-369, and IRGACURE-379 (trade names, all manufactured by BASF Japan Ltd.). In addition, as the acylphosphine-based initiator, it is possible to use a commercially available product IRGACURE-819 or DAROCUR-TPO (trade name, all manufactured by BASF Japan Ltd.).

<Binder Polymer>

In the present invention, the composition may further include a binder polymer as necessary. As the binder polymer, an alkali-soluble resin can be used.

The alkali-soluble resin is an alkali-soluble resin that is a linear high-molecular-weight organic polymer and can be appropriately selected from alkali-soluble resins having at least one group that accelerates alkali solubility in the molecule (preferably a molecule in which an acrylic copolymer or a styrene-based copolymer is used as the main chain). From the viewpoint of heat resistance, a polyhydroxystyrene-based resin, a polysiloxane-based resin, an acrylic resin, an acrylamide-based resin, or an acryl/acrylamide copolymer resin is preferred, and, from the viewpoint of controlling developing properties, an acrylic resin, an acrylamide-based resin, or an acryl/acrylamide copolymer resin is preferred.

Examples of the group that accelerates alkali solubility (hereinafter, also referred to as acid group) include a carboxyl group, a phosphoric acid group, a sulfonic acid group, a phenolic hydroxyl group, and the like, and the acid group is preferably a group that is soluble in an organic solvent and can be developed using a weak alkali aqueous solution and particularly preferably a (meth)acrylic acid group. Only one acid group or two or more acid groups may be used.

Examples of a monomer capable of supplying the acid group after the polymerization include a monomer having a hydroxyl group such as 2-hydroxyethyl (meth)acrylate, a monomer having an epoxy group such as glycidyl (meth)acrylate, and a monomer having an isocyanate group such as 2-isocyanateethyl (meth)acrylate. The number of kinds of the monomers for introducing the acid group may be one or more. In order to introduce the acid group into the alkali-soluble binder, monomers having the acid group and/or monomers capable of supplying the acid group after polymerization (hereinafter, in some cases, also referred to as “monomer for introducing the acid group”) may be polymerized together as monomer components. Meanwhile, in a case in which the acid group is introduced using the monomer capable of supplying the acid group after the polymerization as the monomer component, for example, a treatment for supplying an acid group described below becomes necessary after polymerization.

The linear high-molecular-weight organic polymer used as the alkali-soluble resin is preferably a polymer having a carboxylic acid in a side chain, and regarding the above-described polymer, Paragraph “0561” of JP2012-208494A (“0691” in the specification of the corresponding US2012/0235099A) and the like can be referred to, and the content thereof is incorporated into the specification of the present application.

The alkali-soluble resin also preferably includes a polymer (a) formed by polymerizing monomer components including a compound represented by General Formula (ED) below

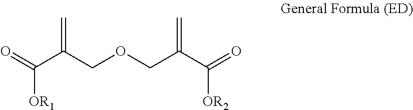

(in Formula (ED), each of R¹ and R² independently represents a hydrogen atom or a hydrocarbon group having 1 to 25 carbon atoms.) (hereinafter, in some cases, also referred to as “ether dimer”) as an essential component as a polymer component (A) which is an essential component. In such a case, the composition of the present invention is capable of forming a cured coated film having extremely excellent transparency as well as heat resistance. In General Formula (ED) representing the ether dimer, the hydrocarbon group having 1 to 25 carbon atoms which is represented by R¹ or R² is not particularly limited, and examples thereof include linear or branched alkyl groups such as methyl, ethyl, n-propyl, isopropyl, n-butyl, isobutyl, t-butyl, t-amyl, stearyl, lauryl, and 2-ethylhexyl; aryl groups such as phenyl; alicyclic groups such as cyclohexyl, t-butylcyclohexyl, dicyclopentadienyl, tricyclodecanyl, isobornyl, adamantyl, and 2-methyl-2-adamantyl; alkyl groups substituted with an alkoxy such as 1-methoxyethyl or 1-ethoxyethyl; alkyl groups substituted with an aryl group such as benzyl; and the like. Among these, particularly, a substituent of primary or secondary carbon which does not easily leave due to an acid or heat such as methyl, ethyl, cyclohexyl, or benzyl is preferred in terms of heat resistance.

Regarding specific examples of the ether dimer, Paragraph “0565” of JP2012-208494A (“0694” in the specification of the corresponding US2012/0235099A) and the like can be referred to, and the content thereof is incorporated into the specification of the present application.

In the present invention, the proportion of a constitutional unit derived from the ether dimer is preferably in a range of 1% by mol to 50% by mol and more preferably in a range of 1% by mol to 20% by mol of all.

In the present invention, an alkali-soluble phenol resin can also be preferably used. Examples of the alkali-soluble phenol resin include a novolac resin, a vinyl polymer, and the like.

Examples of the novolac resin include resins obtained by condensing a phenol and an aldehyde in the presence of an acid catalyst. Examples of the phenol include phenol, cresol, ethylphenol, butylphenol, xylenol, phenylphenol, catechol, resorcinol, pyrogallol, naphthol, bisphenol A, and the like.

Examples of the aldehyde include formaldehyde, paraformaldehyde, acetaldehyde, propionaldehyde, benzaldehyde, and the like.

The phenol and the aldehyde can be used singly or as a combination of two or more thereof.

Specific examples of the novolac resin include metacresol, paracresol, and condensation products between a mixture thereof and formalin.

The molecular weight distribution of the novolac resin may be adjusted to a desired value using means such as classification. Alternatively, a low-molecular-weight component having a phenol-based hydroxyl group such as bisphenol C or bisphenol A may be mixed with the novolac resin.

The alkali-soluble resin is particularly preferably a benzyl (meth)acrylate/(meth)acrylic acid copolymer or a multicomponent polymer made up of benzyl (meth)acrylate, (meth)acrylic acid, and another monomer. Additionally, examples thereof include substances obtained by copolymerizing 2-hydroxyethyl methacrylates, 2-hydroxypropyl (meth)acrylate/polystyrene macromonomer/benzyl methacrylate/methacrylic acid copolymer, 2-hydroxy-3-phenoxypropyl acrylate/polymethyl methacrylate macromonomer/benzyl methacrylate/methacrylic acid copolymer, 2-hydroxyethyl methacrylate/polystyrene macromonomer/methyl methacrylate/methacrylic acid copolymer, 2-hydroxyethyl methacrylate/polystyrene macromonomer/benzyl methacrylate/methacrylic acid copolymer, all of which are described in JP1995-140654A (JP-H7-140654A), and the like.

The acid value of the alkali-soluble resin is preferably in a range of 30 mgKOH/g to 200 mgKOH/g, more preferably in a range of 50 mgKOH/g to 150 mgKOH/g, and still more preferably in a range of 70 mgKOH/g to 120 mgKOH/g.

In addition, the weight-average molecular weight (Mw) of the alkali-soluble resin is preferably in a range of 2,000 to 50,000, more preferably in a range of 5,000 to 30,000, and still more preferably in a range of 7,000 to 20,000.

Regarding the alkali-soluble resin, Paragraphs “0558” to “0571” of JP2012-208494A (“0685” to “0700” in the specification of the corresponding US2012/0235099A) can be referred to, and the content thereof is incorporated into the specification of the present application.

The content of the binder polymer in the present invention can be set to 80% by mass or lower of the total solid content of the composition, can also be set to 50% by mass or lower, and can also be set to 30% by mass or lower.

<Surfactant>

The composition of the present invention may include a surfactant. As the surfactant, a variety of surfactants such as a fluorine-based surfactant, a nonionic surfactant, a cationic surfactant, an anionic surfactant, and a silicone-based surfactant can be used.

Particularly, when the composition of the present invention includes at least any one of a fluorine-based surfactant and a silicone-based surfactant, the liquid characteristics (particularly, fluidity) are further improved when a coating fluid is produced, and thus it is possible to further improve the evenness of the coating thickness or liquid-saving properties.

That is, in a case in which a film is formed using a coating fluid to which the composition including at least any one of fluorine-based surfactants and silicone-based surfactants is applied, the surface tension between a surface to be coated and the coating fluid decreases and thus the wetting properties with respect to the surface to be coated are improved and the coating properties with respect to the surface to be coated are improved. Therefore, in a case in which a thin film having a thickness of approximately several micrometers is formed using a small amount of the fluid as well, the inclusion of the surfactant is effective since a film having a uniform thickness with little thickness variation is more preferably formed.

The content of fluorine in the fluorine-based surfactant can be set, for example, in a range of 3% by mass to 40% by mass.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F479, MEGAFACE F482, MEGAFACE F554, MEGAFACE F780, MEGAFACE R08 (all manufactured by DIC Corporation), FLUORAD FC430, FLUORAD FC431, FLUORAD FC171 (all manufactured by Sumitomo 3M, Ltd.), SURFLON S-382, SURFLON S-141, SURFLON S-145, SURFLON SC-101, SURFLON SC-103, SURFLON SC-104, SURFLON SC-105, SURFLON SC1068, SURFLON SC-381, SURFLON SC-383, SURFLON S393, SURFLON KH-40 (all manufactured by AGC Seimi Chemical Co., Ltd.), EFTOP EF301, EFTOP EF303, EFTOP EF351, EFTOP EF352 (all manufactured by Mitsubishi Materials Electronic Chemicals Co., Ltd. (formerly Jemco Inc.)), PF636, PF656, PF6320, PF6520, PF7002 (manufactured by OMNOVA Solution Inc.), and the like.

As the fluorine-based surfactant, a polymer having a fluoroaliphatic group can be used. Examples of the polymer having a fluoroaliphatic group include a fluorine-based surfactant having a fluoroaliphatic group, which is obtained from a fluoroaliphatic compound produced using a telomerization method (also referred to as a telomer method) or an oligomerization method (also referred to as an oligomer method).

Here, the “telomerization method” refers to a method for synthesizing a compound having one or two active groups in a molecule by polymerizing substances with a low molecular weight. In addition, the “oligomerization method” refers to a method of converting a monomer or a mixture of monomers to an oligomer.

Examples of the fluoroaliphatic group in the present invention include a —CF₃ group, a —C₂F₅ group, a —C₃F₇ group, a —C₄F₉ group, a —C₅F₁₁ group, a —C₆F₁₃ group, a —C₇F₁₅ group, a —C₈F₁₇ group, a —C₉F₁₉ group, and a —C₁₀F₂₁ group, and, for compatibility and coatability, a —C₂F₅ group, a —C₃F₇ group, a —C₄F₉ group, a —C₅F₁₁ group, a —C₆F₁₃ group, a —C₇F₁₅ group, or a —C₈F₁₇ group can be used.

The fluoroaliphatic compound in the present invention can be synthesized using the method described in JP2002-90991A.

As the polymer having the fluoroaliphatic group in the present invention, a copolymer of a monomer having the fluoroaliphatic group in the present invention, (poly(oxyalkylene)) acrylate, and/or (poly(oxyalkylene)) methacrylate can be used. This copolymer may be an irregularly-distributed copolymer or a block-copolymerized copolymer. In addition, examples of the poly(oxyalkylene) group include a poly(oxyethylene) group, a poly(oxypropylene) group, and a poly(oxybutylene) group, and the poly(oxyalkylene) group may be a unit having alkylene with different chain lengths in the same chain length such as a poly(block-linked body of oxyethylene, oxypropylene, and oxyethylene) group or a poly(block-linked body of oxyethylene and oxypropylene) group. Furthermore, the copolymer of the monomer having the fluoroaliphatic group and (poly(oxyalkylene)) acrylate (or methacrylate) may be not only a 2-membered copolymer but also a 3- or more-membered copolymer obtained by copolymerizing two or more different monomers having a fluoroaliphatic group or two or more different (poly(oxyalkylene)) acrylates (or methacrylates) and the like at the same time.

Examples of a commercially available surfactant including a polymer having a fluoroaliphatic group in the present invention include the surfactants described in Paragraph “0552” in JP2012-208494A (“0678” in the specification of US2012/0235099A) and the content thereof is incorporated into the specification of the present application. In addition, it is possible to use MEGAFACE F-781 (manufactured by DIC Corporation), a copolymer of an acrylate (or methacrylate) having a C₆F₁₃ group, (poly(oxyethylene)) acrylate (or methacrylate), and (poly(oxypropylene) acrylate (or methacrylate)), a copolymer of an acrylate (or methacrylate) having a C₈F₁₇ group and (poly(oxyalkylene)) acrylate (or methacrylate), a copolymer of an acrylate (or methacrylate) having a C₈F₁₇ group, (poly(oxyethylene)) acrylate (or methacrylate), and (poly(oxypropylene)) acrylate (or methacrylate), or the like.

Specific examples of the nonionic surfactants include the nonionic surfactants described in Paragraph “0553” in JP2012-208494A (“0679” in the specification of the corresponding US2012/0235099A), the contents of which is incorporated into the specification of the present application.

Specific examples of cationic surfactants include the cationic surfactants described in Paragraph “0554” in JP2012-208494A (“0680” in the specification of the corresponding US2012/0235099A) and the contents thereof can be incorporated into the specification of the present application.

Specific examples of the anionic surfactants include W004, W005, W017 (manufactured by Yusho Co., Ltd.), and the like.

Examples of silicone-based surfactants include the silicone-based surfactants described in Paragraph “0556” in JP2012-208494A (“0682” in the specification of the corresponding US2012/0235099A) and the contents thereof can be incorporated into the specification of the present application. In addition, examples thereof also include “TORAY SILICONE SF8410”, TORAY SILICONE SF8427”, TORAY SILICONE SH8400”, “ST80PA”, “ST83PA”, “ST86PA” all manufactured by Dow Corning Toray Co., Ltd., “TSF-400”, “TSF-401”, “TSF-410”, “TSF-4446” all manufactured by Momentive Performance Materials Inc., “KP321”, “KP323”, “KP324”, “KP340” all manufactured by Shin-Etsu Chemical Co., Ltd., and the like.

The amount of the surfactant added can be set in a range of 0.0001% by mass to 2% by mass of the total solid content of the composition of the present invention, can also be set in a range of 0.005% by mass to 1.0% by mass, and can also be set in a range of 0.01% by mass to 0.1% by mass. Only one surfactant may be used singly, or two or more surfactants may be combined together.

<Other Components>

In the composition of the present invention, in addition to the above-described essential components or the above-described additives, other components can be appropriately selected and used depending on the purpose as long as the effect of the present invention is not impaired.

Examples of other components that can be jointly used include a binder polymer, a dispersing agent, a sensitizer, a crosslinking agent, a curing accelerator, a filler, a thermal curing accelerator, a thermopolymerization inhibitor, a plasticizer, and the like and, furthermore, an accelerator of adhesion to the surface of a base material and other auxiliary agents (for example, conductive particles, a filler, a defoamer, a flame retardant, a levelling agent, a peeling accelerator, an antioxidant, a fragrance, a surface tension adjuster, a chain transfer agent, and the like) may also be jointly used.

When the composition of the present invention appropriately includes the above-described components, it is possible to adjust properties such as stability and film properties of the target near infrared radiation-absorbing filter.

Regarding the above-described components, for example, the descriptions in Paragraphs “0183” and thereafter in JP2012-003225A (“0237” and thereafter in the specification of the corresponding US2013/0034812A), Paragraphs “0101” and “0102”, Paragraphs “0103” and “0104”, and Paragraphs “0107” to “0109” in JP2008-250074A, and the like can be referred to and the contents thereof can be incorporated into the specification of the present application.

Since the composition of the present invention can be produced in a liquid form, a near infrared radiation cut-off filter can be easily produced by, for example, directly applying and drying the composition of the present invention, and it is possible to improve production suitability which has been insufficient in the above-described near infrared radiation cut-off filter of the related art.

In the near infrared radiation cut-off filter of the present invention, before and after being heated at 180° C. or higher (more preferably at 200° C. or higher) for five minutes, the percentage of change in absorbance at a wavelength of 400 nm and the percentage of change in absorbance at a wavelength of 800 nm are both preferably 10% or lower and more preferably 5% or lower.

In addition, in the near infrared radiation cut-off filter of the present invention, before and after being left to stand at a high temperature and a high humidity of 85° C. and 95% RH for two hours or longer (more preferably for three hours or longer), the percentages of change in absorbance ratio obtained using the following expression are preferably 10% or lower, more preferably 7% or lower, and still more preferably 4% or lower, respectively.

[(Absorbance ratio before test-absorbance ratio after test)/absorbance ratio before test]

Here, the absorbance ratio refers to (maximum absorbance in a wavelength range of 700 nm to 1400 nm/minimum absorbance in a wavelength range of 400 nm to 700 nm).

The film thickness of the near infrared radiation cut-off filter of the present invention is not particularly limited and can be appropriately selected depending on the purpose. For example, the film thickness thereof is preferably in a range of 1 μm to 500 μm, more preferably in a range of 1 μm to 300 μm, and particularly preferably in a range of 1 μm to 200 μm. In the present invention, even in a case in which the thickness of the near infrared radiation cut-off filter is as thin as described above, high near infrared radiation-shielding properties can be maintained.

Examples of the use of the near infrared radiation-absorbing composition of the present invention include a near infrared radiation cut-off filter on the light-receiving side of a solid-state imaging element substrate (for example, a near infrared radiation cut-off filter for a wafer-level lens, or the like), a near infrared radiation cut-off filter on the back surface side (the side opposite to the light-receiving side) of a solid-state imaging element substrate, and the like. The near infrared radiation-absorbing composition of the present invention is preferably used for a light shielding film on the light-receiving side of a solid-state imaging element substrate. Particularly, the near infrared radiation-absorbing composition of the present invention is preferably directly applied onto an imaging sensor for a solid-state imaging element so as to form a coated film.

In a case in which a near infrared radiation cut-off layer is formed by coating the near infrared radiation-absorbing composition of the present invention, the viscosity of the near infrared radiation-absorbing composition of the present invention is preferably in a range of 1 mPa·s to 3000 mPa·s, more preferably in a range of 10 mPa·s to 2000 mPa·s, and still more preferably in a range of 100 mPa·s to 1500 mPa·s.

In a case in which the near infrared radiation-absorbing composition of the present invention is used for a near infrared radiation cut-off filter on a light-receiving side of a solid-state imaging element substrate and forms a near infrared radiation cut-off layer by being applied, from the viewpoint of a property for forming a thick film and uniform coatability, the viscosity of the near infrared radiation-absorbing composition is preferably in a range of 10 mPa·s to 3000 mPa·s, more preferably in a range of 500 mPa·s to 1500 mPa·s, and still more preferably in a range of 700 mPa·s to 1400 mPa·s.

The present invention may be a laminate including a near infrared radiation cut-off layer obtained by curing the near infrared radiation-absorbing composition and a dielectric multilayer film. Examples of an aspect of the present invention include (i) an aspect in which a transparent support body, the near infrared radiation cut-off layer, and the dielectric multilayer film are provided in the above-described order and (ii) an aspect in which the near infrared radiation cut-off layer, a transparent support body, and the dielectric multilayer film are provided in the above-described order. Examples of the above-described transparent support body include a glass substrate and a transparent resin substrate.

The dielectric multilayer film is a film having a capability of reflecting and/or absorbing near infrared radiation.

As a material for the dielectric multilayer film, for example, a ceramic material can be used. Alternatively, a noble metal film absorbing light in the near infrared radiation range may be used in consideration of thickness and the number of layers so that the visible light transmittance of the near infrared radiation cut-off filter is not affected.

As the dielectric multilayer film, specifically, a constitution in which high-refractive-index material layers and low-refractive-index material layers are alternately laminated can be preferably used.

As a material for constituting the high-refractive-index material layer, a material having a refractive index of 1.7 or higher can be used, and a material having a refractive index generally in a range of 1.7 to 2.5 is selected.

Examples of the above-described material include titanium oxide (titania), zirconium oxide, tantalum pentaoxide, niobium pentaoxide, lanthanum oxide, yttrium oxide, zinc oxide, zinc sulfide, indium oxide, and a material containing the above-described oxide as a main component and a small amount of titanium oxide, tin oxide, and/or cerium oxide. Among these, titanium oxide (titania) is preferred.

As a material for constituting the low-refractive-index material layer, a material having a refractive index of 1.6 or lower can be used, and a material having a refractive index generally in a range of 1.2 to 1.6 is selected.

Examples of the above-described material include silica, alumina, lanthanum fluoride, magnesium fluoride, and sodium aluminum hexafluoride. Among these, silica is preferred.

The thickness of each of the high-refractive-index material layer and the low-refractive-index material layer is generally a thickness of 0.1λ, to 0.5λ of the wavelength λ, (nm) of an infrared ray to shield. When the thickness is outside the above-described range, the product (n×d) of the refractive index (n) and the film thickness (d) becomes significantly different from the optical film thickness computed from λ/4, and thus the relationship of optical characteristics such as reflection and refraction is destroyed, and there is a tendency that the control of shielding and permeation of light having a specific wavelength becomes difficult.

In addition, the number of layers laminated in the dielectric multilayer film is preferably in a range of 5 to 50 and more preferably in a range of 10 to 45.

The near infrared radiation cut-off filter is used for lenses having a function of absorbing and cutting near infrared radiation (optical lenses such as a lens for a camera such as a digital camera, a mobile phone, or an in-vehicle camera, an f-θ lens, and a pick-up lens), optical filters for a light-receiving element in a semiconductor device, near infrared radiation-absorbing films or near infrared radiation-absorbing plates shielding heat rays for energy saving, agricultural coating agents intended for selective use of sunlight, recording media in which near infrared radiation-absorbed heat is used, near infrared radiation filters for an electronic device or a photograph, protective glasses, sunglasses, heat ray-shielding films, optical letter-read and recording, prevention of copying classified documents, electrophotographic photoreceptors, laser fusion, and the like. In addition, the near infrared radiation cut-off filter is also useful for a noise cut-off filter for a CCD camera and a filter for a CMOS image sensor.

Furthermore, a production method of a near infrared radiation cut-off filter of the present invention preferably includes a step of forming a film (a near infrared radiation cut-off filter) by applying the near infrared radiation-absorbing composition (preferably through coating or printing and still more preferably through applicator coating) and a step of drying the film. The film thickness, the laminate structure, and the like can be appropriately selected depending on the purpose.

A support body may be a transparent substrate made of glass or the like, a solid-state imaging element substrate, another substrate (for example, a glass substrate 30 described below) provided on the light-receiving side of the solid-state imaging element substrate, or a layer such as a flattened layer provided on the light-receiving side of the solid-state imaging element substrate.

The near infrared radiation-absorbing composition (coating fluid) can be applied to the support body using a method such as, for example, spin coating, slit spin coating, slit coating, screen printing, applicator application, or the like.

In addition, the conditions for drying the coated film vary depending on the kind and used proportions of individual components and a solvent; however, generally, the coated film is dried at a temperature in a range of 60° C. to 200° C. for approximately 30 seconds to 15 minutes.

A method for forming a near infrared radiation cut-off filter using the near infrared radiation-absorbing composition of the present invention may include other steps. The other steps are not particularly limited and can be appropriately selected depending on the purpose. Examples thereof include a surface treatment step of the base material, a preheating step (prebaking step), a curing treatment step, a post heating step (post baking step), and the like.

<Preheating Step and Post Heating Step>

The heating temperatures in the preheating step and the post heating step are generally in a range of 80° C. to 200° C. and preferably in a range of 90° C. to 180° C.

The heating times in the preheating step and the post heating step are generally in a range of 30 seconds to 400 seconds and preferably in a range of 60 seconds to 300 seconds.

<Curing Treatment Step>

The curing treatment step refers to a step of carrying out a curing treatment on the formed film as necessary and the curing treatment improves the mechanical strength of the near infrared radiation cut-off filter.

The curing treatment step is not particularly limited and can be appropriately selected depending on the purpose and preferred examples thereof include a full-surface exposure treatment, a full-surface thermal treatment, and the like. In the present invention, the meaning of “exposure” includes the irradiation of the surface with radioactive rays such as electron beams or X rays as well as light rays having a variety of wavelengths.

The exposure is preferably carried out through irradiation with radioactive rays and, as the radioactive rays that can be used in the exposure, particularly, ultraviolet rays such as electron beams, KrF, ArF, g-rays, h-rays, or i-rays or visible light are preferably used. Preferably, KrF, g-rays, h-rays, or i-rays are preferred.

Examples of the exposure method include stepper exposure, exposure using a high-pressure mercury lamp, and the like.

The exposure amount is preferably in a range of 5 mJ/cm² to 3000 mJ/cm², more preferably in a range of 10 mJ/cm² to 2000 mJ/cm², and particularly preferably in a range of 50 mJ/cm² to 1000 mJ/cm².

Examples of a method for the full-surface exposure treatment include a method in which the full surface of the above-described formed film is exposed. In a case in which the near infrared radiation-absorbing composition includes the polymerizing compound, the full-surface exposure accelerates the curing of a polymerizing component in the film formed of the composition, makes the film cured to a greater extent, and improves the mechanical strength and the durability.

An apparatus for carrying out the full-surface exposure is not particularly limited and can be appropriately selected depending on the purpose, and preferred examples thereof include UV steppers such as ultrahigh-pressure mercury lamps.

In addition, examples of the method for the full-surface thermal treatment include a method in which the full surface of the above-described formed film is heated. The heating of the full surface increases the film strength of a pattern.

The heating temperature during the full-surface heating is preferably in a range of 120° C. to 250° C. and more preferably in a range of 120° C. to 250° C. When the heating temperature is 120° C. or higher, the film strength is improved by the heating treatment and, when the heating temperature is 250° C. or lower, components in the film are decomposed and it is possible to prevent the film from becoming weak and brittle.

The heating time in the full-surface heating is preferably in a range of 3 minutes to 180 minutes and more preferably in a range of 5 minutes to 120 minutes.

An apparatus for carrying out the full-surface heating is not particularly limited and can be appropriately selected from well-known apparatuses depending on the purpose, and examples thereof include a drying oven, a hot plate, an IR heater, and the like.

In addition, the present invention also relates to a camera module having a solid-state imaging element substrate and a near infrared radiation cut-off filter disposed on the light-receiving side of the solid-state imaging element substrate, in which the near infrared radiation cut-off filter is the near infrared radiation cut-off filter of the present invention.

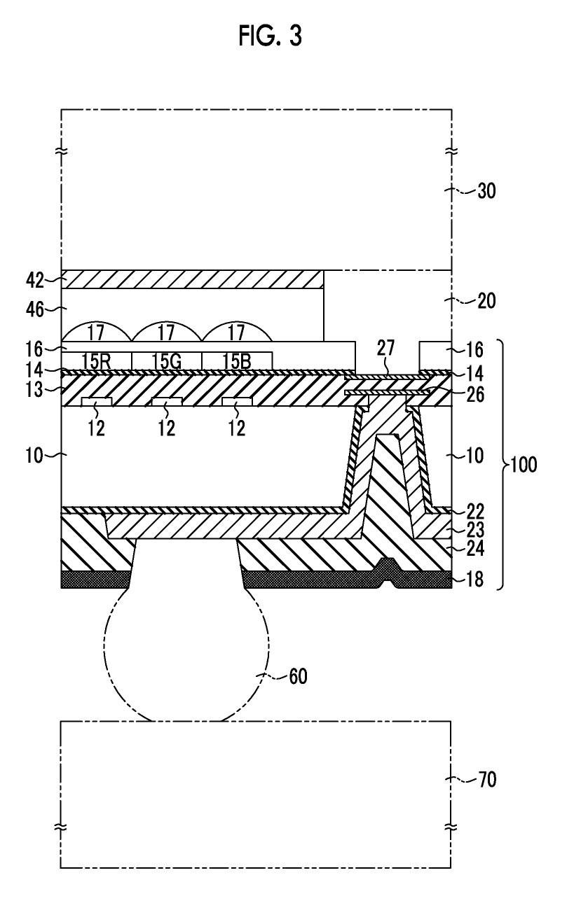

Hereinafter, a camera module according to an embodiment of the present invention will be described with reference to FIGS. 2 and 3, but the present invention is not limited to the following specific example.

Meanwhile, in FIGS. 2 and 3, common reference signs will be given to common portions.

In addition, in the description, “up”, “upward”, and “upside” indicate a side far from a silicon substrate 10, and “down”, “downward”, and “downside” indicate a side close to the silicon substrate 10.

FIG. 2 is a schematic sectional view illustrating the constitution of a camera module including a solid-state imaging element.

A camera module 200 illustrated in FIG. 2 is connected to a circuit board 70, which is a mounting substrate, through solder balls 60, which is a connection member.

In detail, the camera module 200 includes a solid-state imaging element substrate 100 including imaging element sections on a first main surface of the silicon substrate, a flattening layer (not illustrated in FIG. 2) provided on the first main surface side (light-receiving side) of the solid-state imaging element substrate 100, a near infrared radiation cut-off filter 42 provided on the flattening layer, a lens holder 50 which is disposed above the near infrared radiation cut-off filter 42 and includes an imaging lens 40 in an inner space, and a light and electromagnetic shield 44 disposed so as to cover the surrounding of the solid-state imaging element substrate 100 and the glass substrate 30. Meanwhile, the glass substrate 30 (light-permeable substrate) may be provided on the flattening layer. The respective members are adhered together using an adhesive 45.

The present invention is a production method of a camera module including the solid-state imaging element substrate 100 and the near infrared radiation cut-off filter 42 disposed on the light-receiving side of the solid-state imaging element substrate which preferably includes a step of forming the near infrared radiation cut-off filter 42 by applying the near infrared radiation-absorbing composition of the present invention to the light-receiving side of the solid-state imaging element substrate. In the camera module according to the present embodiment, the near infrared radiation cut-off filter 42 can be formed on the flattening layer by, for example, applying the near infrared radiation-absorbing composition of the present invention so as to form a film. The method for applying the near infrared radiation-absorbing composition is as described above.

In the camera module 200, incidence ray ho from the outside sequentially permeates the imaging lens 40, the near infrared radiation cut-off filter 42, the glass substrate 30, and the flattening layer, and then reaches the imaging element section in the solid-state imaging element substrate 100.

The camera module 200 includes the near infrared radiation cut-off filter directly provided on the flattening layer, but the near infrared radiation cut-off filter may be directly provided on a micro lens without the flattening layer, or the near infrared radiation cut-off filter may be provided on the glass substrate 30, or the glass substrate 30 provided with the near infrared radiation cut-off filter may be adhered to the camera module.

FIG. 3 is an enlarged sectional view of the solid-state imaging element substrate 100 in FIG. 2.

The solid-state imaging element substrate 100 includes the imaging elements 12 on the first main surface of the silicon substrate 10, which is a substrate, an interlayer insulating film 13, a base layer 14, a color filter 15, an overcoat 16, and micro lenses 17 in this order. A red color filter 15R, a green color filter 15G, and a blue color filter 15B (hereinafter, these will be collectively referred to as “color filter 15”) or the micro lenses 17 are respectively disposed so as to correspond to the imaging elements 12. A light shielding film 18, an insulating film 22, a metallic electrode 23, a solder resist layer 24, an inner electrode 26, and an element surface electrode 27 are provided on a second main surface which is on a side opposite to the first main surface of the silicon substrate 10. The respective members are adhered together using an adhesive 20.

A flattening layer 46 and the near infrared radiation cut-off filter 42 are provided on the micro lenses 17. The near infrared radiation cut-off filter 42 may be provided on the micro lenses 17 and between the base layer 14 and the color filter 15 or between the color filter 15 and the overcoat 16 instead of being provided on the flattening layer 46. Particularly, the near infrared radiation cut-off filter is preferably provided at a position 2 mm or less (more preferably 1 mm or less) away from the surfaces of the micro lenses 17. When the near infrared radiation cut-off filter is provided at this position, it is possible to simplify the step of forming the near infrared radiation cut-off filter and to sufficiently cut unnecessary near infrared radiation rays travelling toward the micro lenses, and thus the near infrared radiation-shielding properties can be further enhanced.

Regarding the solid-state imaging element substrate 100, the description of the solid-state imaging element substrate 100 in Paragraph “0245” and thereafter (Paragraph “0407” in the specification of the corresponding US2012/068292A) of JP2012-068418A can be referred to, and the content thereof is incorporated into the specification of the present application.

Thus far, an embodiment of the camera module has been described with reference to FIGS. 2 and 3, but the embodiment is not limited to the embodiment of FIGS. 2 and 3.

### EXAMPLES

Hereinafter, the present invention will be more specifically described using examples. Materials, amounts used, proportions, the contents of treatments, the orders of treatments, and the like described in the following examples can be appropriately changed within the scope of the gist of the present invention. Therefore, the scope of the present invention is not limited to specific examples described below.

In the present examples, the following compounds were employed.

A-1: The following compound ((weight-average molecular weight: 2,000), a synthesis example thereof will be described below)

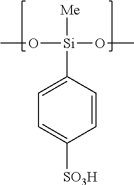

A-2: The following compound ((weight-average molecular weight: 15,000), a synthesis example thereof will be described below)

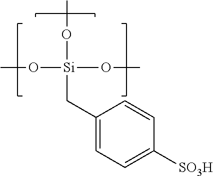

A-3: The following compound ((weight-average molecular weight: 10,000), a synthesis example thereof will be described below)

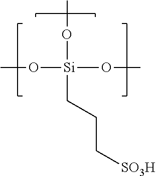

A-4: The following compound ((weight-average molecular weight: 10,000), n1=0.8, n2=0.2, a synthesis example thereof will be described below)

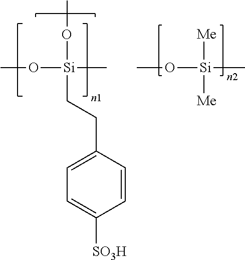

A-5: The following compound (weight-average molecular weight: 10,000, n1=0.8, n2=0.2, a synthesis example thereof will be described below)

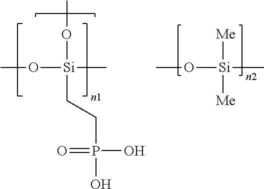

A-6: The following compound (weight-average molecular weight: 10,000, n1=0.8, n2=0.2, a synthesis example thereof will be described below)

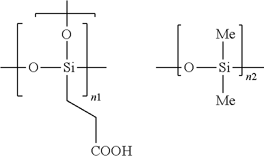

A-7: The following compound (a siloxane having a basket-like structure which included an acid group or a salt thereof; a synthesis example thereof will be described below)

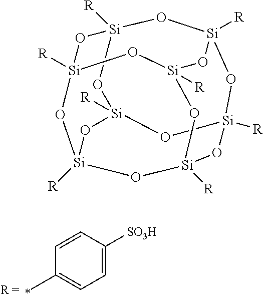

R-1: The following compound (weight-average molecular weight: 10,000, a synthesis example thereof will be described below)

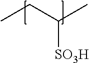

C-1: The following compound

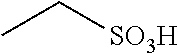

C-2: The following compound

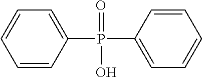 [SMILES: O=P(O)(c1ccccc1)c1ccccc1]

### Synthesis Examples of Compounds (A-1) to (A-7) and (R-1)

The compound (A-1) was synthesized according to the following method.

After toluene (10 g) was dissolved in KBM-802 (manufactured by Shin-Etsu Chemical Co., Ltd.) (10 g, 0.055 mol), an aqueous solution of 50% potassium hydroxide (0.62 g, 0.028 mol) and water (1.69 g) were added to the solution, a Dean-Stark apparatus was attached to the solution, and the solution was heated and refluxed for 12 hours. After that, oxalic acid (0.5 g, 0.0055 mol) was added to the solution. The solvent was distilled away under reduced pressure, thereby obtaining an A-1 precursor (8 g).

Oxone (manufactured by Sigma-Aldrich Co., LLC.) (16.18 g, 0.026 mol) was added to a trifluoroacetic acid solution (50 g) of the obtained A-1 precursor (5 g, 0.0053 mol), and the components were stirred at room temperature for 12 hours. After the end of the reaction, an aqueous solution of saturated sodium hydrocarbon, an aqueous solution of saturated thio sulfuric acid, and 10% hydrochloric acid were added to the solution, and, after salting-out, ethyl acetate was extracted, thereby obtaining a target A-1 (3 g).

The compound (A-2) was synthesized according to the method illustrated in FIG. 1 of Electrochemica Acta 37(9) (1992).

The compound (A-3) was synthesized according to the synthesis method for the compound (A-2).

The compound (A-4) was synthesized according to the method illustrated in FIG. 2 of WO2009/140773A.

The compounds (A-5) and (A-6) were synthesized using the same method as for the compound (A-4).

For the compound (A-7), fuming sulfuric acid (38.76 g, manufactured by Wako Pure Chemical Industries, Ltd., solution of 30% sulfuric acid) was added to 5 g of a PSS-octaphenyl substituted (manufactured by Sigma-Aldrich Co., LLC.), and the solution was heated at 80° C. and stirred for 12 hours. After that, the reaction solution was dropped into a mixture of hexane and ethyl acetate (1:1) (600 mL), and solid was educed. Hot water was added to the obtained solid, and the concentration thereof was adjusted to 16.7%.

Water (60 g) was put into a three-neck flask and was heated at 57° C. in a nitrogen atmosphere. A monomer solution obtained by dissolving vinylsulfonic acid (100 g) in water (160 g) and an initiator solution obtained by dissolving VA-046B (water-soluble azo-based polymerization initiator manufactured by Wako Pure Chemical Industries, Ltd., 2,2′-Azobis[2-(2-imidazolin-2-yl)propane]disulfate dihydrate, 1.164 g, 0.5 mol % of the monomer) in water (80 g) were added thereto dropwise at the same time over two hours. After the end of the dropwise addition, the components were stirred together for two hours, then, were heated to 65° C., and furthermore, were stirred together for two hours, and a reaction was finished, thereby obtaining the compound (R-1).

### Near Infrared Radiation-Absorbing Composition

### Example 1-1

0.5 equivalents of copper hydroxide (0.06 g) of the amount of the acid group in the compound (A-1) was added to the compound (A-1), and the components were stirred at 50° C. for one hour, thereby obtaining a near infrared radiation-absorbing composition.

In addition, in Examples 1-2 to 1-6, near infrared radiation-absorbing compositions 2 to 6 were obtained in the same manner as in Example 1-1 except for the fact that the compound (A-1) was changed to the compounds shown in the following table.

### Example 2-1

0.5 equivalents of copper hydroxide (0.45 g) of the amount of the acid group in the compound (A-7) was added to the compound (A-7), and the components were stirred at 50° C. for one hour, thereby obtaining a copper complex (A-7).

The following compounds were mixed together, thereby preparing a near infrared radiation-absorbing composition 7.

| | |
|---|---|
| Copper complex (A-7) | 75 parts by mass |
| Epoxy resin: JER157S65 | 12.5 parts by mass |
| Polymerizing compound: KAYARAD DPHA | 12.5 parts by mass |
| Solvent: PGMEA | 100 parts by mass |

### Reference Example 1

0.5 equivalents of copper hydroxide (0.06 g) of the amount of the acid group in the compound (R-1) was added to the compound (R-1), and the components were stirred at 50° C. for one hour, thereby obtaining a near infrared radiation-absorbing composition 6.

### Comparative Example 1

0.5 equivalents of copper hydroxide (0.45 g) of the total amount of the acid group in the compound (C-1) was added to an eggplant flask, was heated at 50° C., and was reacted for two hours. After the end of the reaction, the solvent was distilled away using an evaporator, thereby obtaining a copper complex (C-1).

The following compounds were mixed together, thereby preparing a near infrared radiation-absorbing composition 7 of the comparative example.

| | |
|---|---|
| Copper complex (C-1) | 75 parts by mass |
| Epoxy resin: JER157S65 | 12.5 parts by mass |
| Polymerizing compound: KAYRYAD DPHA | 12.5 parts by mass |
| Solvent: PGMEA | 100 parts by mass |

### Comparative Example 2

According to the same method as in Comparative Example 1, a copper complex C-2 was obtained using the compound (C-2). In addition, according to the same method as in Comparative Example 1, a near infrared radiation-absorbing composition 8 of the comparative example was prepared.

<<Production of Near Infrared Radiation Cut-Off Filter>>

Each of the near infrared radiation-absorbing compositions prepared in the examples and comparative examples was applicator-applied onto a glass substrate using an applicator coating method (a baker applicator manufactured by Yoshimits Seiki, used with the slit width of an YBA-3 type adjusted to be 250 μm) and was preheated (prebaked) at 100° C. for 120 seconds. After that, all the samples were heated at 180° C. for 300 seconds on a hot plate, thereby obtaining near infrared radiation cut-off filters having a film thickness of 100 μm.

<<Evaluation of Near Infrared Radiation Shielding Properties>>

The transmittances at a wavelength of 800 nm of the near infrared radiation cut-off filters obtained as described above were measured using a spectrophotometer U-4100 (manufactured by Hitachi High-Technologies Corporation). The near infrared radiation shielding properties were evaluated using the following standards. The results are shown in the following table.

1: Transmittance at 800 nm≦5%

2: 5%<Transmittance at 800 nm≦7%

3: 7%<Transmittance at 800 nm≦10%

4: 10%<Transmittance at 800 nm

<<Evaluation of Heat Resistance>>

The near infrared radiation cut-off filters obtained as described above were left to stand at a predetermined temperature for five minutes. The absorbance of each of the near infrared radiation cut-off filters at 800 nm was measured respectively before and after a heat resistance test, and the percentage of change in absorbance at 800 nm, which was represented by ((absorbance before test-absorbance after test)/absorbance before test)×100(%), was obtained. For the absorbance at 400 nm as well, the percentage of change in absorbance at 400 nm, which was represented by ((absorbance after test-absorbance before test)/absorbance before test)×100(%), was obtained. The heat resistances at the respective wavelengths were evaluated using the following standards. For the measurement of the absorbance, a spectrophotometer U-4100 (manufactured by Hitachi High-Technologies Corporation) was used.

1: When the near infrared radiation cut-off filter was heated at 200° C. or higher, the percentages of change in absorbance were respectively 10% or lower.

2: When the near infrared radiation cut-off filter was heated at a temperature in a range of 180° C. or higher and lower than 200° C., the percentages of change in absorbance were respectively 10% or lower, and the near infrared radiation cut-off filter was colored.

3: When the near infrared radiation cut-off filter was heated at lower than 180° C., the percentages of change in absorbance were respectively 10% or lower.

<<Evaluation of Moisture Resistance>>

The near infrared radiation cut-off filters obtained as described above were left to stand at a high temperature and a high humidity of 85° C. and 95% RH for a predetermined time. The maximum absorbance (Absλmax) at a wavelength in a range of 700 nm to 1400 nm and the minimum absorbance (Absλmin) at a wavelength in a range of 400 nm to 700 nm of each of the near infrared radiation cut-off filters were measured using a spectrophotometer U-4100 (manufactured by Hitachi High-Technologies Corporation) respectively before and after a moisture resistance test, and the absorbance ratio represented by “Absλmax/Absλmin” was obtained. The percentage of change in absorbance ratio represented by |(absorbance ratio before test-absorbance ratio after test)/absorbance ratio before test×100|(%) was evaluated using the following standards.

1: In a case in which the near infrared radiation cut-off filter was left to stand in the above-described high temperature and high humidity for three hours, the percentage of change in absorbance was 10% or lower.

2: In a case in which the near infrared radiation cut-off filter was left to stand in the above-described high temperature and high humidity for two hours, the percentage of change in absorbance was 10% or lower.

3: In a case in which the near infrared radiation cut-off filter was left to stand in the above-described high temperature and high humidity for one hour, the percentage of change in absorbance was 10% or lower.

TABLE 1

| | | Near infrared | | |
|---|---|---|---|---|
| | Siloxane having | radiation- | | |
| | acid group | absorbing | Heat | Humidity |
| | or salt thereof | composition | resistance | resistance |
| Example 1-1 | A-1 | 1 | 1 | 1 |
| Example 1-2 | A-2 | 2 | 1 | 1 |
| Example 1-3 | A-3 | 3 | 1 | 2 |
| Example 1-4 | A-4 | 4 | 1 | 1 |
| Example 1-5 | A-5 | 5 | 2 | 1 |
| Example 1-6 | A-6 | 6 | 2 | 1 |
| Example 2-1 | A-7 | 7 | 1 | 2 |
| Reference | R-1 | 8 | 2 | 1 |
| Example 1 | | | | |
| Comparative | C-1 | 9 | 2 | 3 |
| Example 1 | | | | |
| Comparative | C-2 | 10 | 3 | 3 |
| Example 2 | | | | |

As is clear from the table, it was found that the near infrared radiation-absorbing compositions of the examples were capable of forming a cured film with excellent heat resistance. In addition, it was found that the cured films obtained in the examples were also excellent in terms of humidity resistance. Furthermore, it was found that the cured films obtained in the examples were capable of maintaining high near infrared radiation-shielding properties.

### EXPLANATION OF REFERENCES

1: copper compound including siloxane (A2) having acid group ion and copper ion
2: copper ion
3: main chain
4: side chain
5: acid group ion site
10: silicon substrate
12: imaging element
13: interlayer insulating film
14: base layer
15: color filter
16: overcoat
17: micro lens
18: light shielding film
20: adhesive
22: insulating film
23: metallic electrode
24: solder resist layer
26: inner electrode
27: element surface electrode
30: glass substrate
40: imaging lens
42: near infrared radiation cut-off filter
44: light and electromagnetic shield
45: adhesive
46: flattening layer
50: lens holder
60: solder ball
70: circuit board
100: solid-state imaging element substrate

What is claimed is:

1. A near infrared radiation-absorbing composition comprising:
a copper compound obtained from a reaction between a siloxane (A1) having an acid group or a salt thereof and a copper component.

2. The near infrared radiation-absorbing composition according to claim 1,
wherein the acid group is at least one group selected from a group consisting of a phosphoric acid group, a carboxylic acid group, and a sulfonic acid group.

3. The near infrared radiation-absorbing composition according to claim 1,
wherein the siloxane (A1) includes at least one of a polymer having a repeating unit represented by Formula (A1-1), a cyclic siloxane, a siloxane having a ladder-like structure, a siloxane having a basket-like structure, and a siloxane having a random structure: 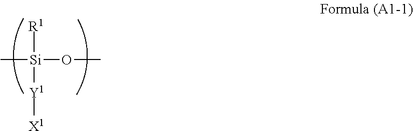
in Formula (A1-1), R¹ represents an alkyl group or an alkoxy group, Y¹ represents a divalent linking group, and X¹ represents an acid group or a salt thereof.

4. The near infrared radiation-absorbing composition according to claim 1,
wherein the acid group is a sulfonic acid group.

5. The near infrared radiation-absorbing composition according to claim 3,
wherein the divalent linking group represents a linear, branched, or cyclic alkylene group, arylene group, —O—, —S—, —C(═O)—, —C(═O)O—, or a group made of a combination thereof.

6. A near infrared radiation-absorbing composition comprising:
a copper complex in which an acid group ion site in a siloxane (A2) having an acid group ion is used as a ligand.

7. A near infrared radiation cut-off filter obtained using the near infrared radiation-absorbing composition according to claim 1.

8. The near infrared radiation cut-off filter according to claim 7,
wherein, before and after heating at 200° C. or higher for five minutes, a percentage of change in absorbance at a wavelength of 400 nm and a percentage of change in absorbance at a wavelength of 800 nm are respectively 10% or lower.

9. A production method for a near infrared radiation cut-off filter, comprising:
forming a near infrared radiation cut-off filter on a light-receiving side of a solid-state imaging element substrate by applying the near infrared radiation-absorbing composition according to claim 1.

10. A camera module comprising:
a solid-state imaging element substrate; and
a near infrared radiation cut-off filter disposed on a light-receiving side of the solid-state imaging element substrate,
wherein the near infrared radiation cut-off filter according to claim 8 is used.

11. A production method for a camera module comprising a solid-state imaging element substrate and a near infrared radiation cut-off filter disposed on a light-receiving side of the solid-state imaging element substrate, comprising:
forming a near infrared radiation cut-off filter by applying the near infrared radiation-absorbing composition according to claim 1 to a light-receiving side of the solid-state imaging element substrate.

12. A method for manufacturing a near infrared radiation-absorbing composition comprising:
reacting a siloxane (A1) having an acid group or a salt thereof with a copper component.

13. The method for manufacturing a near infrared radiation-absorbing composition according to claim 12,
wherein the acid group is at least one group selected from a group consisting of a phosphoric acid group, a carboxylic acid group, and a sulfonic acid group.

14. The method for manufacturing a near infrared radiation-absorbing composition according to claim 12,
wherein the siloxane (A1) includes at least one of a polymer having a repeating unit represented by Formula (A1-1), a cyclic siloxane, a siloxane having a ladder-like structure, a siloxane having a basket-like structure, and a siloxane having a random structure: 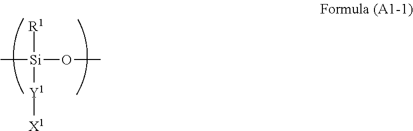
in Formula (A1-1), R¹ represents an alkyl group or an alkoxy group, Y′ represents a divalent linking group, and X¹ represents an acid group or a salt thereof.

15. The method for manufacturing a near infrared radiation-absorbing composition according to claim 12,
wherein the acid group is a sulfonic acid group.

16. The method for manufacturing a near infrared radiation-absorbing composition according to claim 14,
wherein the divalent linking group represents a linear, branched, or cyclic alkylene group, arylene group, —O—, —S—, —C(═O)—, —C(═O)O—, or a group made of a combination thereof.

17. The method for manufacturing a near infrared radiation-absorbing composition according to claim 12, further comprising adding a solvent.
